(19) United States
(12) Patent Application Publication
(10) Pub. No.: US 2026/0239786 A1
(43) Pub. Date: Aug. 13, 2026

(54) ANISOTROPIC CONDUCTIVE CONNECTION STRUCTURE

(71) Applicant: ENJET CO., LTD., Gyeonggi-do (KR)

(72) Inventors: Do Young Byun, Gyeonggi-do (KR); Won-il Son, Gyeonggi-do (KR)

(73) Assignee: ENJET CO., LTD., Gyeonggi-do (KR)

(21) Appl. No.: 19/152,934

(22) PCT Filed: Feb. 1, 2024
(86) PCT No.: PCT/KR2024/001555

§ 371 Date: Jul. 31, 2025

(30) Foreign Application Priority Data
Feb. 8, 2023 (KR) 10-2023-0017063
Apr. 10, 2023 (KR) 10-2023-0047137

(51) Int. Cl. H10H 20/857; C09D 11/037; C09D 11/102; C09D 11/52; H10H 20/832

(52) U.S. Cl. CPC H10H 20/857; C09D 11/037; C09D 11/102; C09D 11/52; H10H 20/832

(57) ABSTRACT

The anisotropic conductive connection method according to the present invention comprises: an application step of applying an anisotropic conductive composition including a metal precursor and a curable resin to at least one first electrode to be bonded; and a pressing step of pressing the anisotropic conductive composition applied on the first electrode between a second electrode opposing the first electrode and the second electrode; a curing step of applying heat or light after applying the anisotropic conductive composition to cure the anisotropic conductive composition to form a cured product, wherein metal sintered bodies connecting the first electrode and the second electrode are formed within the cured product.

### TECHNICAL FIELD

The present invention relates to an anisotropic conductive composition, a connection method, and a connection structure, and more specifically, to an anisotropic conductive material composition, connection method, and connection structure that bond and electrically connect electrodes of a substrate and electrodes of a chip.

### BACKGROUND ART

Anisotropic conductive compositions are used for various applications in the manufacture and assembly of semiconductor packages and microelectronic devices. For example, they are used as compositions for bonding integrated circuit chips to substrates (die bonding adhesives) or as compositions for bonding circuit assemblies to printed circuit boards (surface mounting conductive adhesives).

More specifically, anisotropic conductive paste (ACP) can be used for forming bonding of various electronic hardware including COG assembly (chip-on glass assembly), flip chips on flex assemblies, non-contact smart card module assemblies, and flip chip die attach on flexible substrates or rigid substrates.

Recently, micro LED (Light-emitting diode), also called micro light-emitting diode, means an ultra-small LED with a side size of 100 μm or less, and is one of the important technologies for implementing flat panel display technology.

Micro LEDs have advantages of excellent energy efficiency and optical efficiency compared to existing LEDs, low heat generation per unit area, and can implement very small pixels, so they have high potential for application to ultra-small displays and precision medical devices in addition to lighting. Anisotropic conductive film (ACF) is being used to attach such micro LEDs to electrodes on substrates.

Since the size of micro LEDs used in 4K (3840*2160) flat panel displays was at least 5020 μm or more, bonding processes to attach electrodes using ACF were possible. However, to implement high definition of 8K or higher, the size of micro LEDs becomes smaller to 3020 μm.

Therefore, since the conductive particles currently used in ACF have a diameter in the range of about 3 to 10 μm, which is very large, bonding micro LED chips using conductive particles in the existing method becomes technically problematic. That is, in the case of micro LED chips for implementing high definition, since the spacing between electrodes becomes 30 μm (or pitch) or less, bonding using existing conductive particles is impossible.

Also, in the case of micro LED chips for implementing high definition, conductive ink with a dotting size of 7 μm or less is required, but uniform printing of 7 μm or less with existing inks containing conductive particles is very difficult
(Prior Patent Document 1) Republic of Korea Patent Registration No. 10-1462658 (Registration Date Nov. 11, 2014)

### DISCLOSURE

### Technical Problem

The first aspect of the present invention is proposed to overcome the aforementioned problems, and provides an anisotropic conductive composition capable of bonding even at fine pitches of 30 μm or less while having anisotropic conductive properties, that is, characteristics where electricity does not flow in the X and Y axes and electricity flows only in the Z axis.

The second aspect of the present invention is proposed to overcome the aforementioned problems, and provides an anisotropic conductive connection method in which metal particles formed in the direction of electrical connection are reduced to form sintered bodies.

The third aspect of the present invention is proposed to overcome the aforementioned problems, and provides an anisotropic conductive structure capable of bonding even at fine pitches of 30 μm or less while having anisotropic conductive properties, that is, characteristics where electricity does not flow in the X and Y axes and electricity flows only in the Z axis.

### Technical Solution

### The Present Invention Provides an Anisotropic Conductive Connection Structure Comprising:

a first electrode;
a second electrode opposing the first electrode;
a connection material formed by curing an anisotropic conductive composition provided between the first electrode and the second electrode,
wherein the connection material has at least one or more metal sintered bodies distributed by phase separation from regions where polymers not having electrical conductivity are cured, and has electrical conductivity only in a connection direction of the first electrode and the second electrode.

In the present invention, the anisotropic conductive connection structure provides that the metal sintered body contacts the first electrode and the second electrode to electrically connect. In the present invention, the anisotropic conductive connection structure provides that a spacing between the first electrode and the second electrode is 10 to 10 μm.

In the present invention, the anisotropic conductive connection structure provides that widths of the first electrode and the second electrode are 1 to 1000 μm.

In the present invention, the connection structure provides that the metal sintered body is formed by sintering metal particles in which metal ions are reduced by heat or laser.

In the present invention, the connection structure provides that the metal sintered body is formed by growth and bonding of metal sintered bodies formed on surfaces of the first electrode and the second electrode respectively.

The present invention provides an anisotropic conductive connection structure comprising:
two third electrodes and fourth electrodes arranged side by side while being spaced apart on an x-y plane;
a fifth electrode opposing the third electrode in a z direction and a sixth electrode opposing the fourth electrode in a z direction; and
a connection material formed by curing continuously across the third electrode, the fourth electrode, the fifth electrode, and the sixth electrodes,
wherein the connection material has at least one or more metal sintered bodies distributed by phase separation from polymer regions where polymers not having electrical conductivity are cured, and has electrical conductivity only in the z direction.

In the present invention, the anisotropic conductive connection structure provides that spacings between the third electrode and the fifth electrode, and between the fourth electrode and the sixth electrode are each 10 to 10 μm.

In the present invention, the anisotropic conductive connection structure provides that spacings between the third electrode and the fourth electrode, and between the fifth electrode and the sixth electrode are each 1 to 50 μm, and a width of each electrode is 1 to 1000 μm.

In the present invention, the anisotropic conductive connection structure provides that the third electrode and the fourth electrode are electrodes formed on a substrate, and the fifth electrode and the sixth electrode are electrodes of electronic components.

In the present invention, the connection structure provides that the metal sintered body is formed by sintering metal particles in which metal ions are reduced by heat or laser.

In the present invention, the connection structure provides that the metal sintered body is formed by growth and bonding of metal sintered bodies formed on surfaces of the third electrode and the fifth electrode, and the fourth electrode and the sixth electrode respectively. The present invention provides an anisotropic conductive connection structure wherein the electronic component is a micro LED.

### The Present Invention Provides a Micro LED Structure Comprising:

two third electrodes and fourth electrodes formed on a substrate;
the micro LED chip including a fifth electrode bonded to the third electrode and a sixth electrode bonded to the fourth electrode; and
a connection material formed by curing an anisotropic conductive composition applied continuously across the third electrode, the fourth electrode, the fifth electrode, and the sixth electrode,
wherein the connection material has at least one or more metal sintered bodies distributed by phase separation from polymer regions where polymers not having electrical conductivity are cured, and has electrical conductivity only between electrodes on the substrate and the micro LED electrodes.

In the present invention, the micro LED structure provides that the third electrode and the fourth electrode have a stacked structure of molybdenum-aluminum-molybdenum.

In the present invention, the micro LED structure provides that the fifth electrode and the sixth electrode are gold electrodes.

### The Present Invention Provides an Anisotropic Conductive Connection Structure Comprising:

N lower electrodes arranged side by side while being spaced apart on an x-y plane;
N upper electrodes opposing the lower electrodes; and
a connection material formed by curing an anisotropic conductive composition formed continuously between the lower electrodes and the upper electrodes,
wherein the connection material has at least one or more metal sintered bodies distributed by phase separation from polymer regions where polymers not having electrical conductivity are cured, and has electrical conductivity between the lower electrodes and the upper electrodes.

### Advantageous Effects

The anisotropic conductive composition according to the present invention does not include metal particles inside, so it is applicable even in microelectrodes, and even when applied between electrodes, electricity does not flow in the x and y directions and electricity flows only between the z direction (that is, between the electrode of the substrate and the electrode of the chip), so there is an effect of allowing electricity to flow in a desired direction without occurrence of shorts between electrodes.

The anisotropic conductive connection method according to the present invention can form sintered bodies having electrical conductivity in only one direction using metal components that are reduced and sintered by light or heat. Therefore, even when applied across adjacent electrodes, shorts between electrodes do not occur in other directions, so there is an effect of being able to efficiently connect between microelectrodes with anisotropic conductivity. Also, the process can be simplified using heat or light that does not give impact to electronic components even when irradiated to electronic components.

The anisotropic conductive connection structure according to the present invention has polymer regions and sintered body regions of hybrid structure mixed between electrodes, so even when applied between fine pitch electrodes, electricity does not flow in the x and y directions and electricity flows only between the z direction (that is, between the electrode of the substrate and the electrode of the chip) where the sintered body region extends, so there is an effect of allowing electricity to flow in a desired direction without occurrence of shorts between electrodes.

Accordingly, the present invention can be applied to various fields requiring various anisotropic conductive electrical connections. In particular, it can be preferably applied to connection of micro LEDs, chip on glass (COG) of FPD (flat panel display), chip on film (COF), film on board (FOB), and connector replacement connections (connections between rigid substrates and film materials, and between film materials and film materials).

### BRIEF DESCRIPTION OF DRAWINGS

FIG. 1 is a schematic diagram showing an inter-electrode bonding process using an anisotropic conductive composition according to an embodiment of the present aspect.

FIG. 2 is a schematic diagram showing an inter-electrode bonding process using an anisotropic conductive composition according to another embodiment of the present aspect.

FIG. 3a is an electron microscope photograph when a phase separation inducer is not used, and FIG. 3b is an electron microscope photograph when a phase separation inducer is used.

FIG. 4(a) is a conceptual diagram explaining a connection structure according to the present embodiment.

FIG. 4(b) is a conceptual diagram explaining a connection structure according to another embodiment.

FIG. 5 is a schematic diagram explaining a mechanism in which regions where sintered bodies are located and regions where polymers are located have an anisotropic structure while a plurality are phase-separated from each other according to reduction and sintering of metal particles and curing of curable resin during heat or laser curing according to the present embodiment.

FIG. 6 is a photograph of a cross-section of a portion where anisotropic conductive compositions according to Examples 11, 12, and 13 are cured to connect electrodes.

FIG. 7 is also a photograph of a portion where anisotropic conductive compositions according to Comparative Examples 7 and 12 are cured to connect electrodes.

FIG. 8 is a schematic diagram for evaluating the lighting rate of micro LEDs by printing anisotropic conductive compositions of Examples 1 to 10 and Comparative Examples 1 to 6 across ITO electrodes that are not connected to each other using the manufactured anisotropic conductive composition, and evaluating by sintering and curing the metal precursor and polymer respectively using IR laser (Infrared (IR) Lasers, 1064 nm).

FIG. 9 is a photograph of electrical resistance and short evaluation performance, showing the performance method after connecting and curing anisotropic conductive compositions of Examples 1 to 10 and Comparative Examples 1 to 6 between gold electrodes.

FIGS. 10 and 11 are photographs showing a method of photographing with an electron microscope after curing anisotropic conductive compositions of Example 1, Example 2, Example 3, Example 4, and Example 9 in Experimental Example 2.

FIG. 12 shows electron microscope photographs of curing without chips after applying anisotropic conductive compositions of Example 1, Example 2, and Example 3, and electron microscope photographs of curing after mounting chips.

FIG. 13 is an electron microscope photograph of Example 14, and

FIG. 14 is an electron microscope photograph of Example 19.

FIG. 15 is an electron microscope photograph of Example 29.

FIG. 16 is Example 30,

FIG. 17 is Example 32,

FIG. 18 is Example 33,

FIG. 19 is Example 34,

FIG. 20 is Example 35,

FIG. 21 is Example 36, and

FIG. 22 is an electron microscope photograph of Example 36.

FIG. 23 shows scanning microscope photographs of Example 37 (10 seconds) and Example 38 (30 seconds).

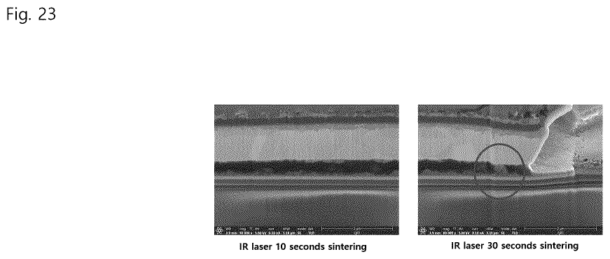

FIG. 24 shows scanning microscope photographs of Example 39 (10 seconds) and Example 39 (30 seconds).

### DETAILED DESCRIPTION OF THE INVENTION

Hereinafter, specific embodiments of the present invention will be described in detail with reference to the drawings. However, the spirit of the present invention is not limited to the presented embodiments, and those skilled in the art who understand the spirit of the present invention can easily propose other embodiments included within the scope of the spirit of the present invention or other inventions that are regressive through addition, change, deletion, etc. of other components within the scope of the same spirit, which shall also be included within the scope of the present invention spirit.

Also, components having the same function within the scope of the same spirit appearing in the drawings of the embodiments are described using the same reference numerals.

Hereinafter, the present invention will be described in more detail with reference to the drawings.

### <First Aspect>

The Example A of the anisotropic conductive composition according to the first aspect of the present invention includes a metal precursor, a phase separation inducer, a curable resin, curing agents for curing the curable resin, and a solvent for dissolving the curable resin and curing agent.

The metal precursor is a material in a state before being reduced to a metal filler having conductivity within the anisotropic conductive composition, and the metal precursor may be a compound including metal hydride, metal hydroxide, metal sulfur oxide, metal nitrate, metal halide, metal complex compound, or combinations thereof.

At this time, the metal precursor may include metals having high electrical conductivity such as silver (Ag), copper (Cu), gold (Au), bismuth, indium, palladium, platinum, nickel, iridium, or alloys thereof, and preferably silver (Ag), which is easily reduced and has high electrical conductivity after reduction and is stable, is included as the first metal.

Also, anions for forming the metal precursor are preferably anions including at least one or combinations thereof selected from the group consisting of hydroxide ion, carboxylic ion, acetate ion, propionate ion, acetylacetonate ion, 2,2,6,6-tetramethyl-3,5-heptanedionate ion, methoxide ion, sec-butoxide ion, t-butoxide ion, n-propoxide ion, i-propoxide ion, ethoxide ion, phosphate ion, alkylphosphonate ion, nitrate ion, perchlorate ion, sulfate ion, alkylsulfonate ion, phenoxide ion, bromide ion, iodide ion, and chloride ion.

The phase separation inducer is a material that induces phase separation of the reduced metal and the cured polymer, and is a material that phase-separates the reduced metal and the cured polymer when the metal precursor is reduced by heat or light (laser) described later. That is, metal ions in the metal precursor state are reduced and sintered, and at this time, they are phase-separated from polymers.

The phase separation inducer includes both hydrophilic groups and lipophilic groups in the molecule, and it is presumed that the hydrophilic group surrounds the reduced conductive metal particle agglomerate (hereinafter referred to as sintered body) at the surface, and the lipophilic group induces phase separation in a manner of contacting the polymer.

At this time, the lipophilic group preferably has 5 to 25 carbon atoms, and the hydrophilic group preferably includes a carboxyl group (—COOH) or an amine group (—NH₂).

Specifically, the phase separation inducer may be fatty acids that are at least one or combinations thereof selected from the group consisting of caprylic acid, pelargonic acid, caproic acid, undecanoic acid, lauric acid, myristic acid, behenic acid, palmitic acid, lignoceric acid, stearic acid, eicosanoic acid, and oleic acid.

Among phase separation inducers, compounds including amines may be, for example, at least one or combinations thereof selected from the group consisting of hexylamine, heptylamine, octylamine, oleylamine, decylamine, dodecylamine, 2-ethylhexylamine, and 1,3-dimethylbutylamine.

At this time, in the phase separation inducer, the hydrophilic group which is a carboxyl group or amine group surrounds the reduced conductive metal particle agglomerate (hereinafter referred to as sintered body) at the surface, and the lipophilic group which is an alkyl group induces phase separation in a manner of contacting the polymer.

When the anisotropic conductive composition is heated by heat or laser to become a cured product in a state where the metal and polymer are phase-separated, the cured product forms a plurality of sintered bodies by reduction of metal ions, and the metal sintered bodies become conductive due to being rich in metal. Also, regions excluding sintered bodies do not have conductivity formed by polymers where the curable resin is cured.

By this phase separation induction method, conductive paths are not formed in the X and Y axes, and conductive paths are formed only in the Z axis so electricity can flow.

The curable resin is a polymer resin for being cured, and for example, resins such as epoxy resins can be used. Epoxy resins that can be used may be materials containing two or more epoxy groups per molecule, such as bisphenol A type epoxy resins, substituted epoxy resins, linear aliphatic epoxy resins, cresol novolac type epoxy resins, biphenyl type epoxy resins, heterocyclic epoxy resins, and halogenated epoxy resins. Also, two or more types of the aforementioned epoxy resins may be used in combination.

The curing agent is a material that cures the curable resin with heat or light, and one or more types of amine or phosphine compounds may be used in combination. For example, as amine curing agents, 2-methyl imidazole, 2,4-dimethylimidazole, 2-ethyl-4-methylimidazole, 2-phenylimidazole, 2-phenyl-4-methylimidazole; as tertiary amine compounds, triethylamine, benzyldimethylamine, methylbenzyldimethylamine, 2-(dimethylaminomethyl) phenol, 2,4,6-tris(dimethylaminomethyl) phenol may be used.

Also, phosphine compounds may be triethylphosphine, tributylphosphine, 1,8-diazabicyclo(5,4,0) undecene-7; or as organic phosphine compounds, triphenylphosphine, trimethylphosphine, triethylphosphine, tributylphosphine, tris(4-methoxyphenyl)phosphine, tri (nonyl phenyl)phosphine may be used.

Also, the curable resin is a polymer resin for being cured, and for example, resins such as acrylic resins can be used. For example, ethyl acrylate, hydroxyethyl acrylate, hydroxypropyl acrylate, 2-ethylhexyl acrylate, butyl acrylate, vinyl butyl ether, vinyl ethyl ether, acrylic acid, methacrylic acid, methyl methacrylate, ethyl methacrylate, isobutyl methacrylate, 2-hydroxyethyl methacrylate, glycidyl methacrylate, etc. can be used, and two or more types of the aforementioned acrylic resins may be used in combination.

The curing agent for curing acrylic resin is a material that cures the curable resin with heat or light, and fat-soluble curing agents such as organic peroxides like lauryl peroxide, benzoyl peroxide, cumene hydroperoxide, diisopropylbenzene hydroperoxide, t-butyl hydroperoxide, and redox curing agents are preferable.

The solvent is for dissolving the aforementioned components, and the solvent can be used without limitation, but it is preferable to use solvents that are at least one or combinations thereof selected from the group consisting of tetrahydrofuran (THF), alcohol-based solvents, ether-based solvents, sulfide-based solvents, toluene-based solvents, xylene-based solvents, benzene-based solvents, alkane-based solvents, oxane-based solvents, amine-based solvents, polyol-based solvents or diketone, amino alcohol, polyamine, ethanol amine, diethanol amine, ethane thiol, propane thiol, butane thiol, pentane thiol, hexane thiol, heptane thiol, octane thiol, nonane thiol, decane thiol, and undecane thiol.

In the aforementioned composition, it is preferable that the phase separation inducer is included in 5 to 15 parts by weight, the curable resin is included in 3 to 8 parts by weight, the curing agent is included in 3 to 8 parts by weight, and the solvent is included in 15 to 25 parts by weight, with respect to 60 parts by weight of the metal precursor.

If the phase separation inducer exceeds the above range relative to the metal precursor, there is a problem of increased electrical resistance, and if it is below the above range, there is a problem that phase separation induction does not occur.

Also, when the curable resin is used in an amount less than the corresponding range, there is a possibility of poor adhesion, and when it exceeds the corresponding range, there is a problem of increased electrical resistance between the micro LED and the substrate electrode.

Also, when the curing agent is included in an amount less than the corresponding range, poor adhesion may occur due to insufficient curing of the curable resin, and when included in an amount greater than the corresponding range, the curing speed of the curable resin becomes fast, making it difficult to obtain sufficient electrical conductivity, or problems may arise where the composition is cured before transfer is completed.

Therefore, within the aforementioned range, the composition can have 5B on the ISO 2409 adhesion test scale, continuous printability >7 days, and laser curing characteristics of 1 minute or less.

Meanwhile, when curing this composition by laser, wavelengths of 760 nm to 4900 nm can be used, and particularly IR with wavelengths of 1000 to 4900 nm is preferable. If outside the above range, damage to electronic components may occur when curing with laser.

Even when reducing and sintering the metal precursor with laser, both materials where the curable resin is cured with heat or light are possible. The reason why curable resin that is cured with heat is possible even when curing with laser is that heat is generated in the electrode by the laser, and the heat generated at this time again provides the heat necessary for curing the curable resin.

Example B of the anisotropic conductive composition according to the first aspect of the present invention includes a metal precursor, a phase separation inducer, a curable resin, curing agents for curing the curable resin, a solvent for dissolving the curing agent, and conductive particles.

The conductive particles may be selected from the group consisting of silver (Ag), gold (Au), indium (In), copper (Cu), ITO (indium tin oxide), palladium, platinum, nickel, and iridium, and nanoparticles having a size in the range of 0.01 to 5.0 μm may be used.

The conductive particles are preferably included in 5 to 15 parts by weight with respect to 60 parts by weight of the metal conductive precursor. Thereby, by adding a small amount of conductive particles, electrical conductivity can be further improved in addition to sintered bodies having electrical conductivity.

Example C of the anisotropic conductive composition according to the first aspect of the present invention includes a metal precursor, a phase separation inducer, a curable resin, curing agents for curing the curable resin, curable resin, an electric field responsiveness controller for EHD (electrohydrodynamic), and conductive particles coated with conductive surface treatment agents.

Meanwhile, the anisotropic conductive composition according to the third embodiment is for use in electrohydrodynamic printing method (EHD), which is a printing technology operated by electric fields according to usage.

The electrohydrodynamic printing method controls the flow of charged composition in an electric field between an electrode and a small nozzle, and the composition is sprayed as thin and long jets under the influence of the electric field, thereby spraying in the form of fine particles or fibers.

For this purpose, an electric field responsiveness controller is added to control the anisotropic conductive composition within the electric field, and particularly in this embodiment, by coating the surface of conductive particles with a conductive surface treatment agent, stable printing can be enabled even at viscosities of 100 cp or higher.

The electric field responsiveness controller can appropriately control the viscosity of printing ink, create finer structures, control electrical conductivity to improve response to electric fields, enable stable spraying of liquid during the printing process to have a more even surface, and also control surface tension of liquid to create precise structures or complex patterns.

The electric field responsiveness controller of this embodiment may include at least one selected from the group consisting of dielectrics, conductive polymers, surfactants, and crosslinking agents as needed.

Preferably, in this embodiment, electrical conductivity can be controlled by using conductive polymers. Without limitation, conductive polymers may be polyaniline (PANI), polypyrrole (PPy), poly(3,4-ethylenedioxythiophene) (PEDOT), and poly(3,4-ethylenedioxythiophene) polystyrene sulfonate (PEDOT:PSS).

Additionally, for electrohydrodynamic printing, ionic compounds such as sodium chloride (NaCl), sulfonic acid, hydrochloric acid, sodium hydroxide (NaOH), potassium hydroxide (KOH), or conductive nanoparticles such as silver (Ag) nanoparticles, gold (Au) nanoparticles, conductive carbon nanoparticles may be further included.

In conductive particles coated with conductive surface treatment agents, the conductive particles may be selected from the group consisting of silver (Ag), gold (Au), indium (In), copper (Cu), ITO (indium tin oxide), palladium, platinum, nickel, and iridium, and particles having a size in the range of 0.01 to 5.0 μm may be used.

The conductive particles are preferably included in 5 to 15 parts by weight with respect to 60 parts by weight of the metal conductive precursor. Thereby, electrical conductivity can be further improved.

The conductive surface treatment agent refers to polymer or monomolecular compounds having polarity in aqueous solution, and is a compound having as functional groups hydroxyl group (—OH), amide group (—CONH₂), ether group (—C—O—C), primary amine (—NH₂), secondary amine (—NHR), tertiary amine (—RNR), carboxyl group (—COO-M+), sulfone group (—SO₂M), phosphate group (—OPO₃M), and sulfate group (—OSO₃M).

Examples of water-soluble polymers include starch, gums, polysaccharide, cellulose having hydroxyl groups, APO (acrylic polyol), PEO (polyethylene oxide), PVA (polyvinyl alcohol), PAAM (polyacrylamide), PVP (Polyvinylpyrrolidone), PAA (Polyacrylic acid), PSSA (polystyrene sulfonic acid), PPA (polyphosphoric acid), PESA (polyethylene sulfonic acid), PEI (polyethylene imide), PA (polyamines), PAMAM (polyamide amine), poly(2-vinylpiperidine salt), and Poly(vinylamine salt).

Examples of monomolecular compounds include caprylic acid, pelargonic acid, caproic acid, undecanoic acid, lauric acid, myristic acid, behenic acid, palmitic acid, lignoceric acid, stearic acid, eicosanoic acid, and oleic acid.

In preferred embodiments of the present invention, the water-soluble polymer preferably has a molecular weight (Mw) in the range of 500 to 1,000,000. Below 500, there are problems of poor electric field responsiveness of EHD and poor adhesion with substrates. On the other hand, above 1,000,000, viscosity becomes very high, making printing difficult.

In preferred embodiments of the present invention, the conductive surface treatment agent, which is the water-soluble polymer or monomolecular compound, has a melting point in the range of 0 to 120° C. Above 120° C., the melting point is high, so the resin exclusion ability of the curable resin is poor, and there are problems that electric path between metal layers does not form. Conversely, when using surface treatment agents having melting points below 0° C., there are disadvantages of difficulty in uniformly dispersing conductive particles at room temperature.

### <Second Aspect>

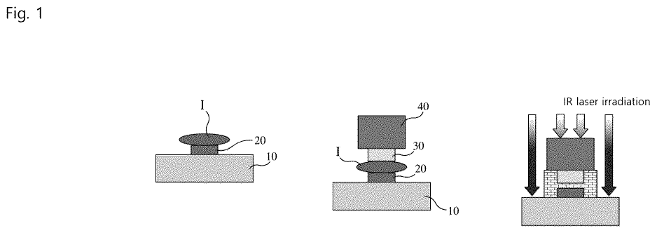

The second aspect of the present invention is an anisotropic conductive connection method. FIG. 1 shows an inter-electrode bonding process using an anisotropic conductive composition according to an embodiment of this aspect. According to this, the anisotropic conductive connection method according to this embodiment includes an application step, a pressing step, and a curing step.

The application step is a step of applying the anisotropic conductive composition on a first electrode. At this time, the anisotropic conductive composition includes a metal precursor, a phase separation inducer, a curable resin, curing agents for curing the curable resin, and a solvent for dissolving the curable resin and curing agent.

In the application step, application of the composition may use one method selected from the group consisting of screen printing, inkjet, doctor blade, slot die, dispenser, eHD printing, spin coating, and pad printing according to the use of the applied product. Descriptions of each method are as follows.

Screen printing: Screen printing is a printing method that delivers ink to a substrate through specially manufactured mesh screens, and has the advantage of being able to print thick paints on various substrates.

Inkjet printing: Inkjet printing is a digital printing method that sprays fine ink droplets through nozzles onto substrates, has high resolution and fast production speed, and is used for flexible substrates and semiconductor devices.

Doctor blade: Doctor blade is a tool with a sharp blade attached used in screen printing processes, used to spread ink evenly and remove excess, improving the quality of electronic printing by increasing ink thickness and consistency.

Slot die: Slot die is a method of coating paints or adhesives on substrates with constant thickness, used in manufacturing electronic components and devices due to precise thickness control and high production efficiency.

Dispenser. A dispenser is a device that precisely places small amounts of ink, adhesive, or paint on substrates, used for various electronic printing tasks such as adhesion of electronic components and device placement.

eHD printing: eHD printing is technology that enables printing with high precision and resolution using electric fields, used for fine electronic devices, organic light-emitting diode (OLED) displays, etc.

Spin coating: Spin coating is a process that forms coating of constant thickness by dropping liquid or gel materials on substrates rotating at high speed, used in various electronic devices and semiconductor processes to create even and thin coatings.

Pad printing: Pad printing is a printing technology that uses soft silicone pads to take ink from printing plates and transfer it to substrates with complex shapes or surfaces, utilized in manufacturing various electronic products as it can print on curved or irregular surfaces of electronic components.

Meanwhile, the metal precursor is dissolved in liquid form as metal salt during application, but functions as conductive metal by being reduced by heat or light. At this time, the reduced conductive metal forms particle agglomerates (hereinafter referred to as sintered bodies) and has metal conductivity.

The phase separation inducer phase-separates the curable resin and the reduced metal precursor from each other when cured by heat or light, so that regions where each metal and resin are located are distinguished in the applied state.

At this time, the reduced metal within the applied coating forms at least one sintered body, and when the region where the curable resin is distributed is called a polymer region, the sintered body is distributed within the polymer.

The curable resin and curing agent are resins suitable for general thermal curing or photocuring, and are cured while forming polymer regions separated from metal by the phase separation inducer during heat or photocuring.

The solvent is a material that dissolves resin, and after dissolution, the viscosity of the composition is preferably 5 to 10,000 cP at 25° C., more preferably 10 to 2,000 cP.

The pressing step is a step of pressing the anisotropic conductive composition (I) applied on the first electrode (20) between the second electrode (30). At this time, the spacing between the first electrode (20) and the second electrode (30) is preferably 10 nm to 10 μm, preferably 10 nm to 1000 nm, preferably 100 to 450 nm, and more preferably 140 to 440 nm. When the spacing exceeds the above range, there are problems of increased contact resistance, and when below the above range, there are problems of weak adhesion.

In the pressing step, since the anisotropic conductive composition has not yet proceeded with reduction of the metal precursor and curing of the polymer resin has not proceeded, pressure can be applied to form the desired spacing.

The curing step is a step of curing the anisotropic conductive composition applied between the first electrode (20) and the second electrode (30) to electrically connect the first electrode (20) and the second electrode (30). At this time, the coating where the anisotropic conductive composition is cured has anisotropic conductivity where electricity flows only in the connection direction of the first electrode (20) and the second electrode (30).

In the curing step, the metal precursor is pressed in the connection direction of the first electrode (20) and the second electrode (30) and reduced by heat or light to become metal sintered bodies, and within the coating, the metal sintered bodies are electrically connected to the first electrode (20) and the second electrode (30) respectively, and directions different from the connection direction of the first electrode (20) and the second electrode (30) are surrounded by polymer regions and not exposed while being spaced apart from each other so electricity does not flow.

The curing step may be performed with one selected from the group consisting of laser, IPL (Intense pulse light), IR (infrared), UV (ultraviolet), and NIR (Near infrared).

Also, curing may be performed by oven or hot plate methods.

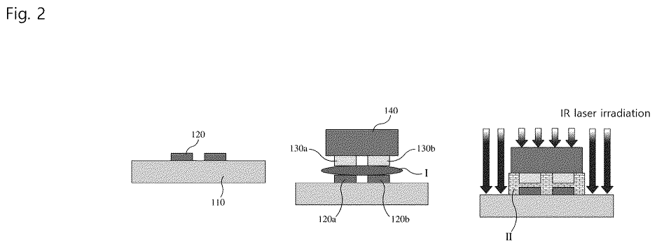

FIG. 2 shows an inter-electrode bonding process using an anisotropic conductive composition according to another embodiment of this aspect. According to this, the anisotropic conductive connection method according to this embodiment includes an application step, a pressing step, and a curing step.

The application step simultaneously applies the anisotropic conductive composition to two electrodes, a third electrode (120a) and a fourth electrode (120b), which are spaced apart and arranged side by side on the x-y plane.

At this time, the anisotropic conductive composition is applied continuously across the two electrodes. The anisotropic conductive composition includes a metal precursor, a phase separation inducer, a curable resin, curing agents for curing the curable resin, and a solvent for dissolving the curable resin and curing agent.

The metal precursor is dissolved in liquid form as metal salt during application, but functions as conductive metal by being reduced by heat or light. At this time, the reduced conductive metal forms at least one sintered body.

The phase separation inducer phase-separates the curable resin and the reduced metal precursor from each other when cured by heat or light, so that regions where each metal and resin are located are distinguished in the applied state.

At this time, the reduced metal within the applied coating is reduced and sintered into at least one sintered body, and when the region where the curable resin is distributed is called a polymer region, the sintered body connects opposing electrodes to each other. At this time, the height of the sintered body is 10 nm to 10 μm, preferably 10 nm to 1000 nm.

The curable resin and curing agent are resins suitable for general thermal curing or photocuring, and are cured while forming polymer regions separated from metal by the phase separation inducer during heat or photocuring.

The solvent is a material that dissolves resin, and after dissolution, the viscosity of the composition is preferably 5 to 10,000 cP at 25° C., more preferably 10 to 2,000 cP.

The pressing step is a step of connecting a fifth electrode (130a) of an electronic component to the upper region of the third electrode (120a) and connecting a sixth electrode (130b) of an electronic component to the upper part of the fourth electrode (120b) in the anisotropic conductive composition applied on the third electrode (120a) and the fourth electrode (120b), and pressing the third electrode (120a) and the fifth electrode (130a) together and pressing the fourth electrode (120b) and the sixth electrode (130b) together.

At this time, the spacing between the third electrode (120a) and the fifth electrode (130a) and the spacing between the fourth electrode (120b) and the sixth electrode (130b) are preferably 10 nm to 10 μm, preferably 10 nm to 1000 nm, preferably 100 to 450 nm, and more preferably 140 to 440 nm. When the spacing exceeds the above range, there are problems of increased contact resistance.

In the pressing step, since the anisotropic conductive composition has not yet proceeded with reduction of the metal precursor and curing of the polymer resin has not proceeded, pressure can be applied to form the desired spacing.

The curing step is divided into a first step where metal is reduced to form a seed layer, and a second step where metal grows and sinters and the binder is cured.

The first step is a process where the metal precursor exists as metal ions in the ink state, and then during the process of reduction of metal ions in the precursor by heat or laser, reduction occurs as metal on the surface of electrode parts of chips and substrates that are made of metal, forming a seed layer.

The second step is where metal particles gradually grow around the seed layer, and simultaneously with the growth of metal particles, they are separated into metal layers and binder layers by the phase separation inducer, and then metal is sintered and binder is cured in different regions respectively.

Accordingly, the anisotropic conductive composition applied between the third electrode (120a) and the fifth electrode (130a) and the fourth electrode (120b) and the sixth electrode (130b) is cured to electrically connect the third electrode (120a) and the fifth electrode (130a) and the fourth electrode (120b) and the sixth electrode (130b). At this time, the coating (II) where the anisotropic conductive composition is cured has anisotropic conductivity where electricity flows only in the connection direction of the third electrode (120a) and the fifth electrode (130a) and the connection direction of the fourth electrode (120b) and the sixth electrode (130b), that is, only in the z direction.

In the curing step, the metal precursor is pressed in the connection direction of the third electrode (120a) and the fifth electrode (130a) and the fourth electrode (120b) and the sixth electrode (130b) and reduced by heat or light to become metal sintered bodies, and within the coating, they are exposed and connected only in the connection direction of the third electrode and the fifth electrode (similarly the connection direction of the fourth electrode and the sixth electrode), and directions different from the connection direction of the third electrode and the fifth electrode (similarly the connection direction of the fourth electrode and the sixth electrode) are surrounded by polymer regions so sintered bodies are spaced apart from each other and electricity does not flow in the horizontal direction.

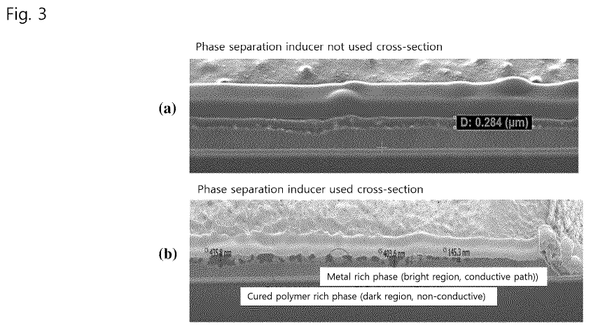

FIG. 3a is an electron microscope photograph when a phase separation inducer is not used, showing that sintered bodies are not formed. On the other hand, FIG. 3b is an electron microscope photograph when a phase separation inducer is used, showing sintered bodies and polymer regions.

Therefore, even when the anisotropic conductive composition forms a coating across the third electrode (120a) and the fourth electrode (120b), electricity does not flow in the connection direction of the third electrode (120a) and the fourth electrode (120b), so shorts do not occur between the third electrode and the fourth electrode.

For example, when the electronic component is a micro LED, even when the fifth electrode (120b) and the sixth electrode (120b) of the micro LED are connected to the fifth electrode and the sixth electrode of the substrate respectively, shorts do not occur and the LED lights up.

Meanwhile, even when reducing and sintering the metal precursor with laser in the curing step, both materials where the curable resin is cured with heat or light are possible. The reason why curable resin that is cured with heat is possible even when curing with laser is that heat is generated in the electrode by the laser, and the heat generated at this time again provides the heat necessary for curing the curable resin.

### <Third Aspect>

The third aspect of the present invention is a connection structure using an anisotropic conductive composition.

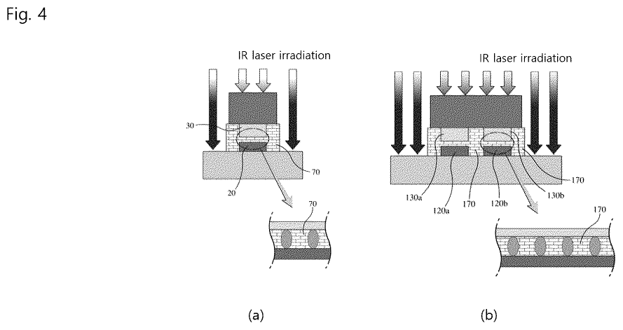

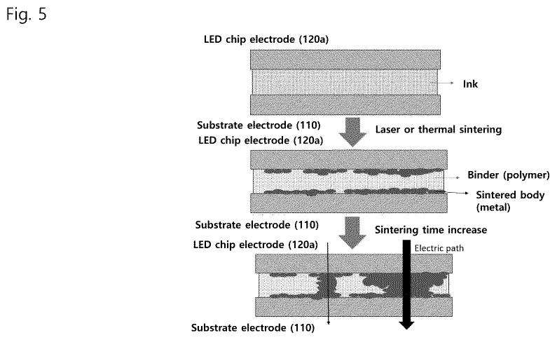

FIG. 4(a) is a conceptual diagram explaining a connection structure according to this embodiment, and the connection structure according to this embodiment includes a first electrode (20), a second electrode (30), and a connection material (70) that electrically connects the first electrode (20) and the second electrode (30).

The first electrode (20) is an electrode for electrical connection formed on a device or substrate, and the material of the electrode is not limited.

The second electrode (30) is an electrode for electrical connection formed on the device or substrate of the first electrode (20), and for example, may be a backplane substrate for attaching electrodes of micro LED chips, and the second electrode (30) is provided at a position opposing the first electrode (20) and may be an electrode having a stacked structure of gold (Au) or molybdenum-aluminum-molybdenum.

At this time, the first electrode (20) and the second electrode (30) each oppose each other, and the spacing between the first electrode (20) and the second electrode (30) is preferably 10 nm to 10 μm, preferably 10 nm to 1000 nm, preferably 100 to 450 nm, and more preferably 140 to 440 nm. When the spacing exceeds the above range, there are problems of increased contact resistance. At this time, the width of each electrode is 1 to 1000 μm, preferably 3 to 80 μm.

The connection material (70) is a material for electrically connecting the first electrode (20) and the second electrode (30), and is an anisotropic conductive connection material so that electricity flows only in the connection direction of the first electrode (20) and the second electrode (30), and electricity does not flow in directions different from the connection direction of the first electrode (20) and the second electrode (30).

At this time, the connection material is located between the first electrode (20) and the second electrode (30) to connect physically and electrically, and during curing, the anisotropic conductive composition between the first electrode (20) and the second electrode (30) is cured while being pressed by pressure.

The anisotropic conductive composition includes a metal precursor, a phase separation inducer, a curable resin, curing agents for curing the curable resin, and a solvent for dissolving the curable resin and curing agent.

The cured coating of the anisotropic conductive composition has a structure where sintered bodies formed by reduction of metal ions derived from the metal precursor are separated from regions where polymers formed by curing of the curable resin are located. At this time, a plurality of regions where sintered bodies are located and regions where polymers are located are mixed with each other.

That is, when the metal precursor exists as metal ions in the ink state, during the process of reduction of metal ions in the precursor by heat or laser, reduction occurs as metal on the surface of electrode parts of chips and substrates that are made of metal, forming a seed layer, and metal particles gradually grow around the seed layer, and simultaneously with the growth of metal particles, they are separated into metal layers and binder layers by the phase separation inducer, and then metal is sintered and binder is cured in different regions respectively.

FIG. 4(b) is a conceptual diagram explaining a connection structure according to another embodiment, and is a connection structure where two electrodes have two opposing electrodes. The connection structure according to this embodiment includes a third electrode (120a), a fourth electrode (120b), a fifth electrode (130a), a sixth electrode (130b), and a connection material (170) that electrically connects the third electrode-fifth electrode and fourth electrode-sixth electrode.

The third electrode (120a) and fourth electrode (120b) are electrodes for electrical connection formed on a substrate, and for example, may be a backplane substrate for attaching micro LEDs, and the fifth electrode is provided at a position opposing the third electrode, with the electrode opposing the third electrode called the fifth electrode and the electrode opposing the fourth electrode called the sixth electrode, and may be an electrode having a stacked structure of molybdenum-aluminum-molybdenum.

The fifth electrode (130a) and sixth electrode (130b) are electrodes for electrical connection formed on devices formed on electronic components, and for example, may be semiconductor chips or micro LED chips. In the case of micro LED chips, the electrodes may be gold, and one electronic component may have two electrodes, the fifth electrode (130a) and sixth electrode (130b), which are positive and negative electrodes.

At this time, the spacing between the third electrode and the fourth electrode (fifth electrode and sixth electrode) is 1 to 50 μm, preferably 3 to 50 μm, and the width of each electrode is 1 to 1000 μm, 3 to 80 μm.

Meanwhile, the spacing between the third electrode and the fifth electrode (fourth electrode and sixth electrode) is preferably 10 nm to 10 μm, preferably 10 nm to 1000 nm, preferably 100 to 450 nm, and more preferably 140 to 440 nm. When the spacing exceeds the above range, there are problems of increased contact resistance.

The connection material is a material for electrically connecting the third electrode and fifth electrode (fourth electrode and sixth electrode), and is an anisotropic conductive connection material where electricity flows only in the connection direction of the third electrode and fifth electrode, and fourth electrode and sixth electrode, and electricity does not flow in directions different from the connection direction of the third electrode and fifth electrode (fourth electrode and sixth electrode).

Therefore, even when the anisotropic conductive composition is connected to the third electrode and fourth electrode and forms a coating across them, electricity does not flow in the connection direction of the third electrode and fourth electrode, so shorts do not occur between the third electrode and fourth electrode.

At this time, the connection material is located between the third electrode and fifth electrode (fourth electrode and sixth electrode) to connect physically and electrically, and during curing, the anisotropic conductive composition between the first electrode and second electrode is cured while being pressed by pressure.

The anisotropic conductive composition includes a metal precursor, a phase separation inducer, a curable resin, curing agents for curing the curable resin, and a solvent for dissolving the curable resin and curing agent.

The cured product of the anisotropic conductive composition has a structure where sintered bodies formed by reduction of metal ions derived from the metal precursor are distributed separately without belonging to polymer regions formed by curing of the curable resin. At this time, sintered body regions and polymer regions are distributed separately from each other.

For example, when the electronic component is a micro LED, when the fifth electrode and sixth electrode of the micro LED are connected to the third electrode and fourth electrode of the substrate respectively, shorts do not occur and the LED lights up.

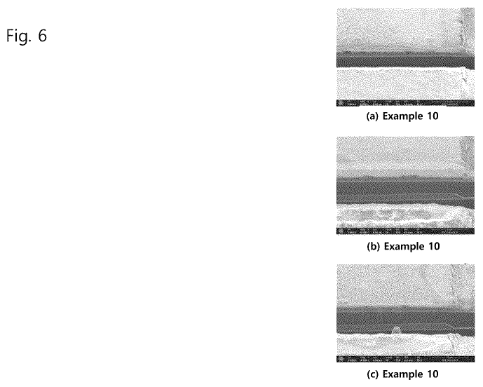

FIG. 5 is a schematic diagram explaining a mechanism in which regions where sintered bodies are located and regions where polymers are located have an anisotropic structure while a plurality are mixed with each other according to reduction and sintering of metal particles and curing of curable resin during heat or laser curing according to this embodiment.

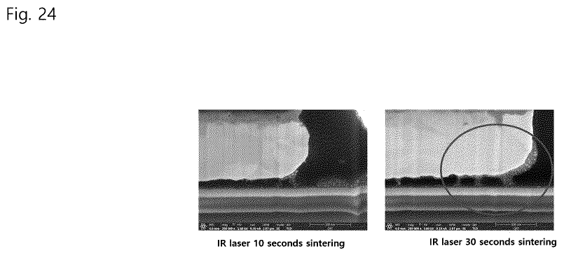

According to this, when sintering metal and curing binder using ink manufactured according to this embodiment, initially metal sintered bodies begin to form on each surface of the LED chip electrode (120a) and the substrate electrode (110). As sintering progresses, metal sintered bodies grow more and more based on the metal sintered bodies formed on the surface, connecting the LED chip electrode (120a) and the substrate electrode (110) to each other (this is confirmed in FIGS. 24 and 25 described later). That is, metal sintered bodies are formed by growth and bonding of metal sintered bodies formed on the LED chip electrode (120a) and substrate electrode (110) surfaces respectively.

In the aforementioned description, the number of electrodes was limited for convenience of explanation, but those skilled in the art will recognize that it can be equally applied to connection structures consisting of N lower electrodes and N upper electrodes opposing them.

### EXAMPLES

Anisotropic conductive compositions of Examples 1 to 10 and Comparative Examples 1 to 6 as shown in Table 1 below were manufactured.

### Manufacturing Example 1

A heating mantle equipped with a stirrer and a 250 ml 3-Neck Round bottom Flask were prepared, and 5.0 g of silver oxide (Ag₂O, Samjeon Pure Chemical) was added to the 3-Neck Round bottom Flask. 60 g of Methanol anhydrous was added here, and the temperature was maintained at 30° C. while stirring at 300 rpm using a stirrer. 2.0 g of 2-Ethylhexylacid and 4.0 g of 2-Ethylhexylamine were gradually added here using a continuous quantitative transfer pump (Cas Science Co., Ltd. PP-150D) at a rate of 0.1 g/min, and stirring was continued for 24 hours while maintaining at 30° C. until the color of the solution changed from black to transparent. The transparent solution was concentrated using a Rotary Evaporator (vacuum rotary concentrator) under vacuum, 85° C. conditions, and viscosity was measured, and concentration was performed until the viscosity reached 5,000 cPs to manufacture a precursor solution containing a silver (Ag) precursor as the first metal precursor.

### Manufacturing Example 2

A 250 ml 3-Neck Round bottom Flask equipped with a stirrer was prepared, and 5.0 g of silver oxide (Ag₂O) and 0.5 g of Indium oxide (In₂O₃) were each added to the 3-Neck Round bottom Flask. 20 g of Acetic acid and 60 g of Methanol anhydrous were added here, and stirring was performed at 300 rpm using a stirrer. 2.0 g of 2-Ethylhexylacid and 4.0 g of 2-Ethylhexylamine were gradually added here, and stirring was continued for 24 hours until the color of the solution became transparent. The transparent solution was concentrated using a Rotary Evaporator (vacuum rotary concentrator) under vacuum, 85° C. conditions until the viscosity reached 4,500 cPs to synthesize a precursor solution containing a silver-indium precursor (Ag-Indium precursor).

### Manufacturing Example 3

A 250 ml 3-Neck Round bottom Flask equipped with a stirrer was prepared, and 3.0 g of Copper(II) formate tetrahydrate was added to the 3-Neck Round bottom Flask 20 g of Acetic acid and 60 g of Methanol anhydrous were added here, and stirring was performed at 300 rpm using a stirrer. 5.0 g of n-butylamine and 1.0 g of 2-Ethylhexylacid were gradually added here, and stirring was continued for 24 hours until the color of the solution became transparent blue. The transparent blue solution was concentrated using a Rotary Evaporator (vacuum rotary concentrator) under vacuum, 85° C. conditions until the viscosity reached 3,000 cPs to synthesize a precursor solution containing a copper precursor.

### <Examples 1 to 10>: Compositions

### Example 1

60 g of the precursor obtained in Manufacturing Example 1 was added to a 100 ml beaker, and 10 g each of butyl acetate and butyl carbitol were added. Using a stirrer, stirring was performed at 300 rpm while maintaining the temperature at 50° C. to completely dissolve, then cooled to room temperature. To the obtained transparent precursor solution, 5 g each of epoxy resin (YD-114E, Kukdo Chemical) and 2-Phenyl-4-methylimidazole were added and completely dissolved while stirring at 300 rpm. Then, 10 g of caprylic acid as a phase separation inducer was added and completely dissolved to manufacture ink.

### <Examples 2 to 3>: Compositions

Same as Example 1, but using precursors obtained in Manufacturing Examples 2 and 3 as shown in Table 1 below and changing the phase separation inducer, Examples 2 and 3 were manufactured.

### Examples 4 to 5

Same as Example 1, but changing the curable resin as shown in Table 1 below, Examples 4 and 5 were manufactured.

### Examples 6 to 7

Same as Example 1, but changing the curing agent as shown in Table 1 below, Examples 6 and 7 were manufactured.

### Examples 8 to 9

Same as Example 1, but further including 10 g each of Ag Nano particle dispersion (20 nm, aldrich, 730793) and Cu Nano particle dispersion (WiNEL Co., Ltd., 60 nm) as metal nanoparticles, and reducing the solvent by the amount that included the metal nanoparticles, Examples 8 and 9 were manufactured.

### Example 10

Same as Example 9, but further including 1.5 g of sulfonic acid as an electric field responsiveness controller, and 50 g of Ag nanoparticles were dispersed in 500 g of ethanol using a homogenizer to manufacture a dispersion solution. To this manufactured dispersion solution, 10 g of PVP (Polyvinylpyrrolidone) with molecular weight 10,000 (Aldrich) as a conductive surface treatment agent was added and completely dissolved while manufacturing a coating solution using a homogenizer, and the coating solution was centrifuged to precipitate metal-coated nanoparticles to manufacture sludge. The manufactured sludge was completely dried using a freeze dryer to manufacture conductive particles coated with PVP, and surface-treated metal particles were used.

### Comparative Example 1

Same as Example 1, but not including a phase separation inducer and increasing the amount of solvent, Comparative Example 1 was manufactured.

### Comparative Example 2

Same as Example 1, but not including curable resin and increasing the amount of solvent, Comparative Example 1 was manufactured.

### Comparative Example 3

Same as Example 1, but not including a phase separation inducer and increasing the amount of solvent, Comparative Example 1 was manufactured.

### Comparative Examples 4 to 5

Same as Example 1, but not including a phase separation inducer and including metal nanoparticles, Comparative Examples 4 and 5 were manufactured.

### Comparative Example 6

Same as Example 1, but not including a metal precursor and including only metal nanoparticles as in the conventional method, Comparative Example 6 was manufactured.

The compositions of the examples and comparative examples are summarized in Tables 1 to 3.

TABLE 1

| | | EX | EX | EX | EX | EX | EX | EX | EX | EX | EX |
|---|---|---|---|---|---|---|---|---|---|---|---|
| Composition | Manufacturer and Model | 1 | 2 | 3 | 4 | 5 | 6 | 7 | 8 | 9 | 10 |
| Metal | ME 1 precursor | 60 | | | 60 | 60 | 60 | 60 | 60 | 60 | 60 |
| conductive | ME 2 precursor | | 60 | | | | | | | | |
| precursor | ME 3 precursor | | | 60 | | | | | | | |
| Phase | caprylic acid | 10 | | | 10 | 10 | 10 | 10 | 10 | 10 | 10 |
| separation | palmitic acid | | 10 | | | | | | | | |
| inducer | Oleic acid | | | 10 | | | | | | | |
| Curable | YD-114E | 5 | 5 | 5 | | | 5 | 5 | 5 | 5 | 4.5 |
| resin | (KUKDO, Bisphenol-A type liquid | | | | | | | | | | |
| | epoxy resin) | | | | | | | | | | |
| | YD-128 | | | | 5 | | | | | | |
| | (KUKDO, Unmodified Bisphenol- | | | | | | | | | | |
| | A based Liquid Epoxy Resin) | | | | | | | | | | |
| | YDF-170 | | | | | 5 | | | | | |
| | (KUKDO, BISPHENOL-F TYPE | | | | | | | | | | |
| | EPOXY RESIN) | | | | | | | | | | |
| Curing | 2-Phenyl-4- | 5 | 5 | 5 | 5 | 5 | | | 5 | 5 | 4.5 |
| agent | methylimidazole(Aldrich) | | | | | | | | | | |
| | 2,4,6- | | | | | | 5 | | | | |
| | Tris(dimethylaminomethyl)phenol(aldrich) | | | | | | | | | | |
| | Tris(4- | | | | | | | 5 | | | |
| | methoxyphenyl)phosphine(Tokyo | | | | | | | | | | |
| | chem) | | | | | | | | | | |
| Metal | Ag Nano particle dispersion | | | | | | | | 10 | | |
| particles | (20 nm, Aldrich, 730793) | | | | | | | | | | |
| | Cu Nano particle | | | | | | | | | 10 | 10 |
| | dispersion(WiNEL, 60 nm) | | | | | | | | | | |
| Electric field | sulfonic acid | | | | | | | | | | 1.5 |
| responsiveness | | | | | | | | | | | |
| controller | | | | | | | | | | | |
| Ink solvent | butyl actetate | 10 | 10 | 10 | 10 | 10 | 10 | 10 | | | |
| | butyl carbitol | 10 | 10 | 10 | 10 | 10 | 10 | 10 | 10 | 10 | 9.5 |

| | | | | | | | | | | |
|---|---|---|---|---|---|---|---|---|---|---|
| Total (wt %) | 100 | 100 | 100 | 100 | 100 | 100 | 100 | 100 | 100 | 100 |

### (EX: Example, CE: Comparative Example, ME: Manufacturing Example)

TABLE 2

| | | EX | EX | EX | EX | EX | EX | EX | EX |
|---|---|---|---|---|---|---|---|---|---|
| Composition | Manufacturer and Model | 21 | 22 | 23 | 24 | 25 | 26 | 27 | 28 |
| Metal | ME 1 precursor | 60 | | | 60 | 60 | 60 | 60 | 60 |
| conductive | ME 2 precursor | | 60 | | | | | | |
| precursor | ME 3 precursor | | | 60 | | | | | |
| Phase | caprylic acid | 10 | | | | | | | |
| separation | palmitic acid | | 10 | | | | | | |
| inducer | Oleic acid | | | 10 | | | | | |
| Curable resin | YD-114E | | | | 5 | | | 5 | 5 |
| | (KUKDO, Bisphenol-A type liquid | | | | | | | | |
| | epoxy resin) | | | | | | | | |
| | YD-128 | | | | | 5 | | | |
| | (KUKDO, Unmodified Bisphenol-A | | | | | | | | |
| | based Liquid Epoxy Resin) | | | | | | | | |
| | YDF-170 | | | | | | 5 | | |
| | (KUKDO, BISPHENOL-F TYPE EPOXY | | | | | | | | |
| | RESIN) | | | | | | | | |
| Curing agent | 2-Phenyl-4-methylimidazole(Aldrich) | | | | 5 | 5 | 5 | | |
| | 2,4,6- | | | | | | | 5 | |
| | Tris(dimethylaminomethyl)phenol(Aldrich) | | | | | | | | |
| | Tris(4- | | | | | | | | 5 |
| | methoxyphenyl)phosphine(Tokyo | | | | | | | | |
| | chem) | | | | | | | | |
| Metal | Ag Nano particle dispersion (20 nm, | | | | | | | | |
| particles | Aldrich, 730793) | | | | | | | | |
| | Cu Nano particle dispersion(WiNEL, | | | | | | | | |
| | 60 nm) | | | | | | | | |
| Electric field | sulfonic acid | | | | | | | | |
| responsiveness | | | | | | | | | |
| controller | | | | | | | | | |
| Ink solvent | butyl actetate | 10 | 10 | 10 | 10 | 10 | 10 | 10 | 10 |
| | butyl carbitol | 10 | 10 | 10 | 10 | 10 | 10 | 10 | 10 |

| | | | | | | | | |
|---|---|---|---|---|---|---|---|---|
| Total (wt %) | 100 | 100 | 100 | 100 | 100 | 100 | 100 | 100 |

### (EX: Example, CE: Comparative Example, ME: Manufacturing Example)

TABLE 3

| Composition | Manufacturer and Model | CE1 | CE2 | CE3 | CE4 | CE5 | CE6 |
|---|---|---|---|---|---|---|---|
| Metal | ME 1 precursor | 60 | 60 | 60 | 80 | 80 | |
| conductive | ME 2 precursor | | | | | | |
| precursor | ME 3 precursor | | | | | | |
| Phase | caprylic acid | | 10 | 10 | | | 10 |
| separation | palmitic acid | | | | | | |
| inducer | Oleic acid | | | | | | |
| Curable resin | YD-114E | 5 | | 5 | 5 | 5 | 5 |
| | (KUKDO, Bisphenol-A type liquid epoxy resin) | | | | | | |
| | YD-128 | | | | | | |
| | (KUKDO, Unmodified Bisphenol-A based | | | | | | |
| | Liquid Epoxy Resin) | | | | | | |
| | YDF-170 | | | | | | |
| | (KUKDO, BISPHENOL-F TYPE EPOXY RESIN) | | | | | | |
| Curing agent | 2-Phenyl-4-methylimidazole(Aldrich) | 5 | 5 | | 5 | 5 | 5 |
| | 2,4,6- | | | | | | |
| | Tris(dimethylaminomethyl)phenol(Aldrich) | | | | | | |
| | Tris(4-methoxyphenyl)phosphine(Tokyo | | | | | | |
| | chem) | | | | | | |
| Metal | Ag Nano particle dispersion (20 nm, Aldrich, | | | | 10 | | |
| particles | 730793) | | | | | | |
| | Cu Nano partide dispersion(WiNEL, 60 nm) | | | | | 10 | 70 |
| Ink solvent | butyl actetate | 20 | 15 | 15 | 5 | 5 | 5 |
| | butyl carbitol | 10 | 10 | 10 | 5 | 5 | 5 |

| | | | | | | |
|---|---|---|---|---|---|---|
| Total (wt %) | 100 | 100 | 100 | 110 | 110 | 100 |

### (EX: Example, CE: Comparative Example, ME: Manufacturing Example)

### <Examples 11 to 20>: Structures

Two electrodes stacked with Mo/Al/Mo with an inter-electrode distance of 10 μm were formed on a glass substrate, and anisotropic conductive compositions of Examples 1 to 10 and Comparative Examples 1 to 6 were applied connecting on the two electrodes, and two electrodes of micro LEDs were opposed and pressed on the electrodes on the substrate. Thereafter, the anisotropic conductive composition was processed with laser (IR laser (Infrared (IR) Lasers, 1064 nm) sintering times of 10 seconds and 30 seconds to sinter and cure the metal precursor and polymer respectively to bond micro LEDs on the substrate as Examples 11 to 19. However, Example 20 was processed the same as Example 1 but thermal curing was performed instead of laser curing. At this time, thermal curing was performed at 150° C. for 40 minutes (conventional oven) for sintering and curing.

### <Comparative Examples 7 to 12>: Structures

Two electrodes stacked with Mo/Al/Mo with an inter-electrode distance of 10 μm were formed on a glass substrate, and anisotropic conductive compositions of Comparative Examples 1 to 6 were applied to span continuously on the two electrodes, and two gold (Au) electrodes of micro LEDs were pressed to oppose the two electrodes on the substrate. Thereafter, the anisotropic conductive composition was cured to bond micro LEDs on the substrate as Comparative Examples 7 to 12.

### <Examples 21 to 23>: Compositions

Example 21 was the same as Example 1 but used octylamine as the phase separation inducer, Example 22 was the same as Example 2 but used 2-ethylhexylamine, and Example 23 was the same as Example 3 but used 1,3-dimethylbutylamine respectively.

### Example 24

Example 24 was the same as Example 1 but used hydroxyethyl acrylate and benzoyl peroxide curing agent.

### Example 25

Example 25 was the same as Example 1 but used ethyl methacrylate and benzoyl peroxide curing agent.

### Example 26

Example 26 was the same as Example 1 but used ethyl methacrylate and benzoyl peroxide curing agent.

### Example 27

Example 27 was the same as Example 1 but used hydroxyethyl acrylate and t-butyl hydroperoxide curing agent.

### Example 28

Example 28 was the same as Example 1 but used hydroxyethyl acrylate and diisopropylbenzene hydroperoxide curing agent.

### Examples 29 to 36

Structures Examples 21 to 28 were manufactured as structures connecting micro LEDs on substrates the same as Example 1.

### <Examples 37 to 40> Structures

### Example 37

The same process as Example 11 was performed, but using laser (IR laser (Infrared (IR) Lasers, 1064 nm)) with a sintering time of 10 seconds to sinter and cure the metal precursor and polymer respectively.

### Example 38

The same process as Example 11 was performed, but using laser (IR laser (Infrared (IR) Lasers, 1064 nm) with a sintering time of 30 seconds to sinter and cure the metal precursor and polymer respectively.

### Example 39

The same process as Example 11 was performed, but using laser (IR laser (Infrared (IR) Lasers, 1064 nm) (in the example, please set a specific point, for example, 1500 nm) with a sintering time of 10 seconds to sinter and cure the metal precursor and polymer respectively.

### Example 40

The same process as Example 11 was performed, but using laser (IR laser (Infrared (IR) Lasers, 1064 nm) (in the example, please set a specific point, for example, 1500 nm)) with a sintering time of 30 seconds to sinter and cure the metal precursor and polymer respectively.

### <Examples 41 to 45> Structures

The same process as Example 11 was performed, but with laser wavelengths of 786, 862, 1122, 1573, 2200, and 2796 nm respectively, and a sintering time of 30 seconds to sinter and cure the metal precursor and polymer respectively.

### Comparative Examples 13 to 16

The same process as Example 11 was performed, but with laser wavelengths of 266, 343, 355, and 532 nm respectively, and a sintering time of 30 seconds to sinter and cure the metal precursor and polymer respectively.

### EXPERIMENTAL EXAMPLES

### Experimental Example 1

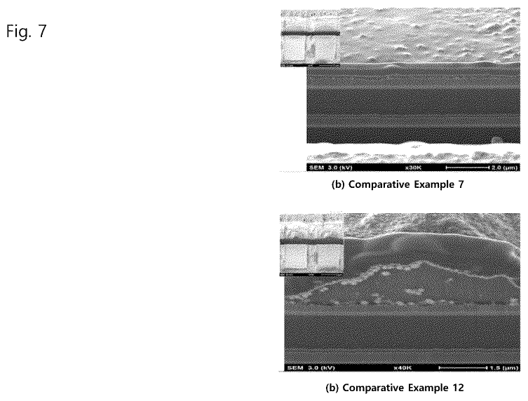

Confirmation of Alternating Phase Formation of Cured Product Cross-sections of portions where anisotropic conductive compositions according to Examples 11, 12, and 13 were cured to connect electrodes were photographed and shown in FIG. 6 respectively. According to this, it was confirmed that regions having sintered bodies with conductivity and polymer regions without conductivity were formed in the cross-section.

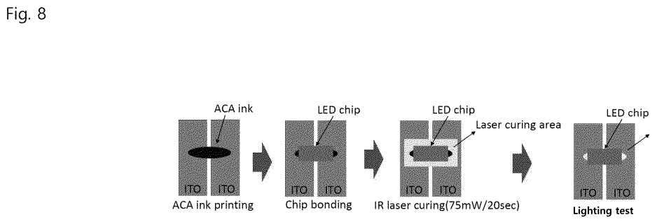

Also, portions where anisotropic conductive compositions according to Comparative Examples 7 and 12 were cured to connect electrodes were photographed and shown in FIG. 7. According to this, in Comparative Example 7 which did not include a phase separation inducer, metal sintered bodies were not formed, and Comparative Example 12 which included only metal nanoparticles without metal precursor did not form metal sintered bodies confirmed as metal nanoparticles dispersed.

### <Experimental Example 2> Lighting Evaluation

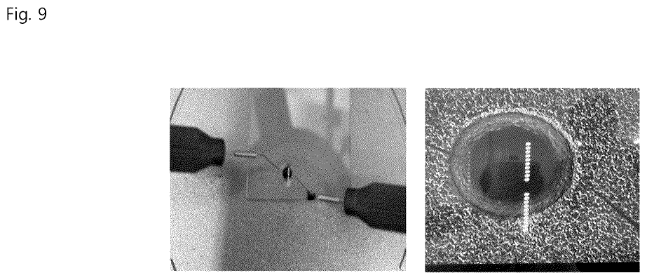

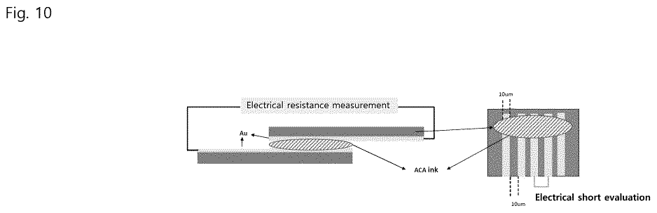

The lighting rate evaluation of micro LEDs was performed by printing anisotropic conductive compositions of Examples 1 to 10 and Comparative Examples 1 to 6 across ITO electrodes that were not connected to each other using the manufactured anisotropic conductive composition as shown in FIG. 8, and evaluating by sintering and curing the metal precursor and polymer respectively using IR laser (Infrared (IR) Lasers, 1064 nm). FIG. 9 is a photograph of performing actual lighting experiments.

### <Experimental Example 3> Resistance and Short Evaluation

Electrical resistance and short evaluation were performed by connecting anisotropic conductive compositions of Examples 1 to 10 and Comparative Examples 1 to 6 between gold electrodes and curing, then performing by the method shown in FIG. 9, and summarized in Table 2.

### <Experimental Example 4> Electron Microscope Photographs

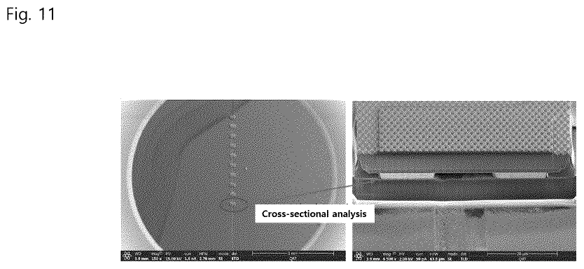

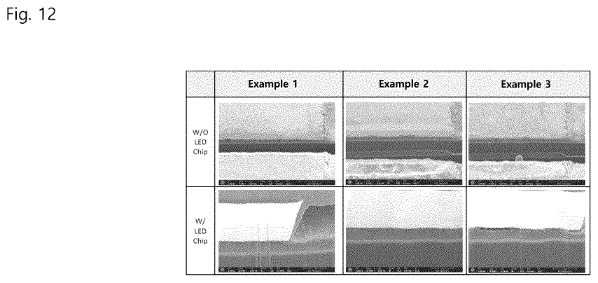

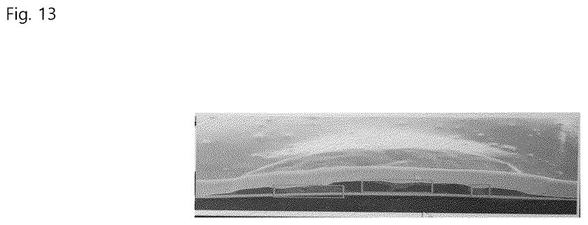

After curing anisotropic conductive compositions of Example 1, Example 2, Example 3, Example 4, and Example 9 in Experimental Example 2, photographs of cured portions taken with electron microscope as shown in FIGS. 10 and 11 are shown in FIGS. 12 and 13 respectively. According to this, it can be confirmed that metal sintered bodies are formed inside the cured products according to the examples.

FIG. 12 shows electron microscope photographs of curing without chips after applying anisotropic conductive compositions of Example 1, Example 2, and Example 3, and electron microscope photographs of curing after mounting chips. The photographs cured without chips are photographs taken at an oblique angle after cutting. The photographs cured after mounting chips are photographs of cut cross-sections.

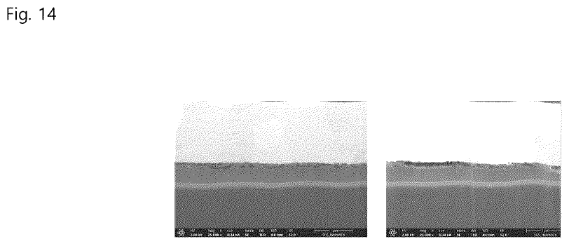

FIG. 13 is an electron microscope photograph of Example 14, and FIG. 14 is an electron microscope photograph of Example 19.

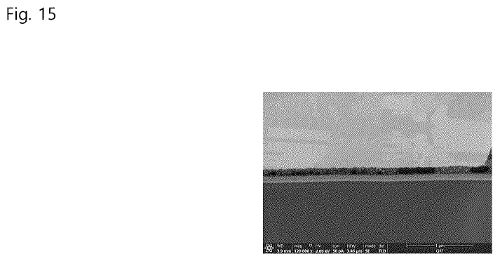

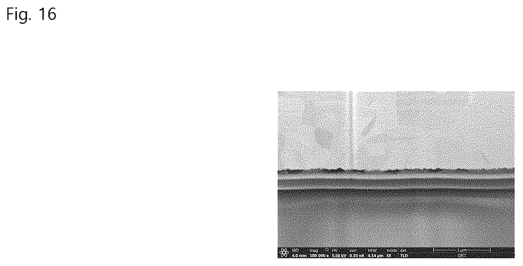

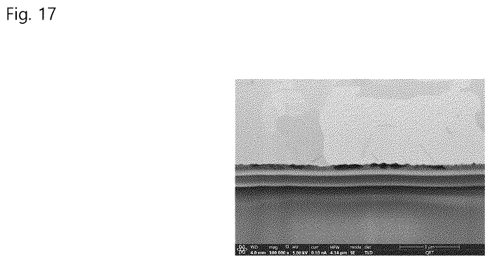

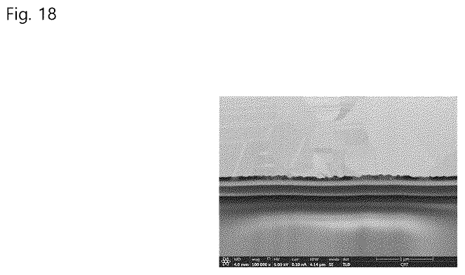

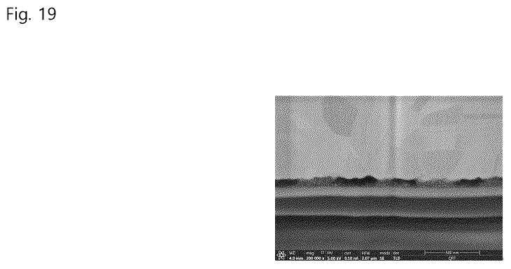

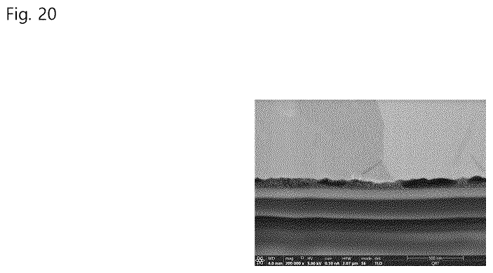

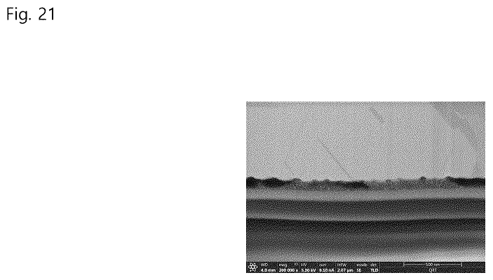

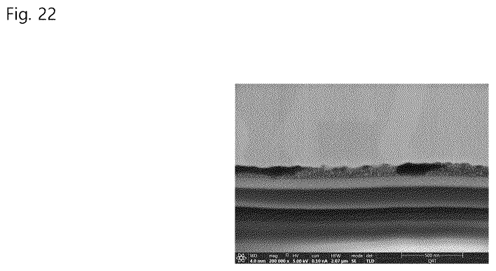

FIG. 15 is an electron microscope photograph of Example 29. FIG. 16 is Example 30, FIG. 17 is Example 32, FIG. 18 is Example 33, FIG. 19 is Example 34, FIG. 20 is Example 35, FIG. 21 is Example 36, and FIG. 22 is an electron microscope photograph of Example 36.

FIG. 24 shows scanning microscope photographs after performing sintering time of 30 seconds for Example 37 and Example 38. FIG. 25 shows scanning microscope photographs after performing sintering time of 10 seconds for Example 39 and Example 40.

### Experimental Example 5

### Adhesion was Performed According to ASTM D3359.

The evaluation results of Experimental Examples 2, 3, and 5 are summarized in Tables 4 and 5.

TABLE 4

| | | EX | EX | EX | EX | EX | EX | EX | EX | EX | EX | CE | CE | CE | CE | CE | CE |
|---|---|---|---|---|---|---|---|---|---|---|---|---|---|---|---|---|---|
| | | 11 | 12 | 13 | 14 | 15 | 16 | 17 | 18 | 19 | 20 | 7 | 8 | 9 | 10 | 11 | 12 |
| Physical | Electrical | x | x | x | x | x | x | x | x | x | x | ∘ | ∘ | ∘ | ∘ | ∘ | ∘ |
| property | short | | | | | | | | | | | | | | | | |
| evaluation | Contact | 0.5 | 0.5 | 0.5 | 0.5 | 0.5 | 0.5 | 0.5 | 0.5 | 0.49 | 0.48 | 0.5 | 0.5 | 0.5 | 0.5 | 20 | 90 |
| | resistance | | | | | | | | | | | | | | | | |
| | (Ω) | | | | | | | | | | | | | | | | |
| | Lighting | 100 | 100 | 100 | 100 | 100 | 100 | 100 | 100 | 100 | 100 | 0 | 0 | 0 | 5 | 10 | 30 |
| | rate of | | | | | | | | | | | | | | | | |
| | Micro | | | | | | | | | | | | | | | | |
| | LED (%) | | | | | | | | | | | | | | | | |
| | Adhesion | 5B | 5B | 5B | 5B | 5B | 5B | 5B | 5B | 5B | 5B | 5B | 0B | 0B | 5B | 5B | 5B |
| | (cross- | | | | | | | | | | | | | | | | |
| | cut test, | | | | | | | | | | | | | | | | |
| | ASTM | | | | | | | | | | | | | | | | |
| | D3359) | | | | | | | | | | | | | | | | |

TABLE 5

| | | EX 29 | EX 30 | EX 31 | EX 32 | EX 33 | EX 34 | EX 35 | EX 36 |
|---|---|---|---|---|---|---|---|---|---|
| Physical | electrical short | x | x | x | x | x | x | x | x |
| property | Contact | 0.5 | 0.5 | 0.5 | 0.5 | 0.5 | 0.5 | 0.5 | 0.5 |
| evaluation | resistance (Ω) | | | | | | | | |
| | Lighting rate of | 100 | 100 | 100 | 100 | 100 | 100 | 100 | 100 |
| | Micro LED (%) | | | | | | | | |
| | Adhesion (cross- | 5B | 5B | 5B | 5B | 5B | 5B | 5B | 5B |
| | cut test, ASTM | | | | | | | | |
| | D3359) | | | | | | | | |

(EX: Example, CE: Comparative Example, ME: Manufacturing Example)

### Experimental Example 6

With Examples 39 to 44 and Comparative Examples 13 to 16, experiments were conducted the same as Experimental Examples 2, 3, and 5 and summarized in Table 6.

TABLE 6

| | | EX | EX | EX | EX | EX | EX | CE | CE | CE | CE |
|---|---|---|---|---|---|---|---|---|---|---|---|
| Item | | 39 | 40 | 41 | 42 | 43 | 44 | 13 | 14 | 15 | 16 |
| Sintering | Laser | 786 | 852 | 1122 | 1573 | 2200 | 2796 | 266 | 343 | 355 | 532 |
| and curing | wavelength | | | | | | | | | | |
| conditions | (nm, | | | | | | | | | | |
| | application | | | | | | | | | | |
| | time fixed at | | | | | | | | | | |
| | 30 seconds) | | | | | | | | | | |
| Physical | electrical | x | x | x | x | x | x | x | x | x | x |
| property | short | | | | | | | | | | |
| evaluation | Contact | 0.4 | 0.5 | 0.5 | 0.5 | 0.5 | 0.5 | 0.5 | 0.5 | 0.5 | 0.5 |
| | resistance | | | | | | | | | | |
| | (Ω) | | | | | | | | | | |
| | Lighting | 100 | 100 | 100 | 100 | 100 | 100 | 0 | 0 | 0 | 0 |
| | rate of | | | | | | | | | | |
| | Micro LED | | | | | | | | | | |
| | (%) | | | | | | | | | | |
| | Adhesion | 5B | 5B | 5B | 5B | 5B | 5B | 5B | 5B | 5B | 5B |
| | (cross-cut | | | | | | | | | | |
| | test, ASTM | | | | | | | | | | |
| | D3359) | | | | | | | | | | |
| | Remarks | | | | | | | chip | chip | chip | chip |
| | | | | | | | | damage | damage | damage | damage |

(EX: Example, CE: Comparative Example, ME: Manufacturing Example)

The above description is merely an exemplary explanation of the present invention, and those skilled in the art to which the present invention belongs will be able to make various modifications without departing from the essential characteristics of the present invention. Therefore, the embodiments disclosed in this specification are not for limiting the present invention but for explaining it, and the spirit and scope of the present invention are not limited by these embodiments. The protection scope of the present invention should be interpreted by the claims below, and all technologies within the equivalent scope should be interpreted as being included in the scope of rights of the present invention.

What is claimed is:

1. An anisotropic conductive connection structure comprising: a first electrode; a second electrode opposing the first electrode; a connection material formed by curing an anisotropic conductive composition provided between the first electrode and the second electrode, wherein the connection material has at least one or more metal sintered bodies distributed by phase separation from regions where polymers not having electrical conductivity are cured, and has electrical conductivity only in a connection direction of the first electrode and the second electrode.

2. The anisotropic conductive connection structure of claim 1, wherein the metal sintered body contacts the first electrode and the second electrode to electrically connect.

3. The anisotropic conductive connection structure of claim 1, wherein a spacing between the first electrode and the second electrode is 10 to 10 μm.

4. The anisotropic conductive connection structure of claim 1, wherein widths of the first electrode and the second electrode are 1 to 1000 μm.

5. The anisotropic conductive connection structure of claim 1, wherein the metal sintered body is a connection structure formed by sintering metal particles in which metal ions are reduced by heat or laser.

6. The anisotropic conductive connection structure of claim 1, wherein the metal sintered body is a connection structure in which metal sintered bodies formed on surfaces of the first electrode and the second electrode respectively grow and are bonded to each other.

7. An anisotropic conductive connection structure comprising: two third electrodes and fourth electrodes arranged side by side while being spaced apart on an x-y plane; a fifth electrode opposing the third electrode in a z direction and a sixth electrode opposing the fourth electrode in a z direction; and a connection material formed by curing continuously across the third electrode, the fourth electrode, the fifth electrode, and the sixth electrodes, wherein the connection material has at least one or more metal sintered bodies distributed by phase separation from polymer regions where polymers not having electrical conductivity are cured, and has electrical conductivity only in the z direction.

8. The anisotropic conductive connection structure of claim 7, wherein spacings between the third electrode and the fifth electrode, and between the fourth electrode and the sixth electrode are each 10 to 10 μm.

9. The anisotropic conductive connection structure of claim 7, wherein spacings between the third electrode and the fourth electrode, and between the fifth electrode and the sixth electrode are each 1 to 50 μm, and a width of each electrode is 1 to 1000 μm.

10. The anisotropic conductive connection structure of claim 7, wherein the third electrode and the fourth electrode are electrodes formed on a substrate, and the fifth electrode and the sixth electrode are electrodes of electronic components.

11. The anisotropic conductive connection structure of claim 1, wherein the metal sintered body is a connection structure formed by sintering metal particles in which metal ions are reduced by heat or laser.

12. The anisotropic conductive connection structure of claim 1, wherein the metal sintered body is a connection structure in which metal sintered bodies formed on surfaces of the third electrode and the fifth electrode, and the fourth electrode and the sixth electrode respectively grow and are bonded to each other.

13. The anisotropic conductive connection structure of claim 7, wherein the electronic component is a micro LED.

14. A micro LED structure comprising: two third electrodes and fourth electrodes formed on a substrate; the micro LED chip including a fifth electrode bonded to the third electrode and a sixth electrode bonded to the fourth electrode; and a connection material formed by curing an anisotropic conductive composition applied continuously across the third electrode, the fourth electrode, the fifth electrode, and the sixth electrode, wherein the connection material has at least one or more metal sintered bodies distributed by phase separation from polymer regions where polymers not having electrical conductivity are cured, and has electrical conductivity only between electrodes on the substrate and the micro LED electrodes.

15. The micro LED structure of claim 14, wherein the third electrode and the fourth electrode have a stacked structure of molybdenum-aluminum-molybdenum.

16. The micro LED structure of claim 15, wherein the fifth electrode and the sixth electrode are gold electrodes.

17. An anisotropic conductive connection structure comprising: N lower electrodes arranged side by side while being spaced apart on an x-y plane; N upper electrodes opposing the lower electrodes; and a connection material formed by curing an anisotropic conductive composition formed continuously between the lower electrodes and the upper electrodes, wherein the connection material has at least one or more metal sintered bodies distributed by phase separation from polymer regions where polymers not having electrical conductivity are cured, and has electrical conductivity between the lower electrodes and the upper electrodes.
